(19) United States
(12) Patent Application Publication
(10) Pub. No.: US 2026/0337781 A1
(43) Pub. Date: Oct. 29, 2026

(54) MICROWAVE PLASMA CHEMICAL VAPOR DEPOSITION OF LOW HYDROGEN SILICON NITRIDE

(71) Applicant: Applied Materials, Inc., Santa Clara, CA (US)

(72) Inventors: Sze Chieh Tan, Singapore (SG); Vicknesh Sahmuganathan, Singapore (SG); Hao-Chun Kao, San Ramon, CA (US); Christian W. Valencia, Alhambra, CA (US); Thai Cheng Chua, Cupertino, CA (US); Kashish Sharma, Santa Clara, CA (US); John Sudijono, Singapore (SG)

(73) Assignee: Applied Materials, Inc., Santa Clara, CA (US)

(21) Appl. No.: 19/189,490

(22) Filed: Apr. 25, 2025

(51) Int. Cl. C23C 16/511; C23C 16/34; H01J 37/32; H10P 14/60; H10P 14/694

(52) U.S. Cl. CPC C23C 16/511; C23C 16/345; H01J 37/32192; H01J 37/3244; H10P 14/6336; H10P 14/6682; H10P 14/69433; H01J 2237/3321

(57) ABSTRACT

Methods of depositing silicon nitride films with low hydrogen content are described. The method may be used in the manufacture of logic and memory semiconductor devices. Methods include flowing a gas stream comprising a silicon-containing compound and a reactant into a processing chamber. The gas stream is ignited to form a microwave plasma, and a semiconductor substrate is exposed to the microwave plasma to form a silicon nitride film on the surface of the semiconductor substrate.

### TECHNICAL FIELD

Embodiments of the present disclosure pertain to the field of electronic device manufacturing and, in particular, to integrated circuit (IC) manufacturing. More particularly, embodiments of the disclosure are directed to methods of depositing silicon nitride (SiN) films having a low hydrogen content.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature, and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

Silicon nitride (SiₓN_{y}) is widely used in microfabrication (e.g., as etch-stop layer, electrical insulator, antireflection coatings, or as a hardmask for dry-etching of semiconductor materials) and CMOS electronic integrated circuits (e.g.,diffusion barriers and passivation layers). Properties of silicon nitride, including broadband transparency and low index-contrast with silicon dioxide, make it highly valuable in photonics. Silicon nitride is particularly useful for creating low-loss, low-phase-error waveguides and is a strong candidate to supplement or replace silicon-on-insulator in silicon photonics. Over the past two decades, silicon nitride has advanced ultra-low-loss waveguides, chip-scale nonlinear photonics, and applications in telecommunications, sensing, and metrology due to high refractive index, flexible dimension control, and superior interface properties. Hydrogen bonds (Si-H and N-H) in SiN films, however, cause high propagation loss, particularly in the telecom spectrum (1510-1565 nm for conventional "C" band and 1260-1360 nm for original "O" band).

Silicon nitride films are typically deposited using low-pressure chemical vapor deposition (LPCVD) or plasma enhanced chemical vapor deposition (PECVD). To mitigate hydrogen content, techniques like annealing or using hydrogen-free precursor gases (e.g., switching from NH₃ to N₂) are employed, but the high temperature results in damage to underlying metal layers and other temperature-sensitive components. There is, therefore, a need in the art for methods of depositing silicon nitride films that have a low hydrogen content.

### SUMMARY

One or more embodiments of the disclosure are directed to a method of forming a film. In one or more embodiments, the method comprises: flowing a gas stream comprising a silicon-containing compound and a reactant into a processing chamber; igniting the gas stream to form a microwave plasma; and exposing a semiconductor substrate to the microwave plasma to form a silicon nitride film on a surface of the semiconductor substrate.

Other embodiments are directed to methods of forming silicon nitride films. In one or more embodiments, the method comprises: exposing a semiconductor substrate to a microwave plasma to form the silicon nitride film, the microwave plasma comprising a silicon-containing compound.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a cross-sectional view of a processing tool according to one or more embodiments;

FIG. 2 illustrates a process flow diagram of a method in accordance with one or more embodiments of the disclosure;

FIG. 3A illustrates a schematic cross-sectional view of a substrate during the method according to one or more embodiments;

FIG. 3B illustrates a schematic cross-sectional view of a substrate during the method according to one or more embodiments; and

FIG. 3C illustrates a schematic cross-sectional view of a substrate during the method according to one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A "substrate", "substrate surface", or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term "substrate surface" is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms "reactive compound," "reactive gas," "reactive species," "precursor," "process gas," and the like are used interchangeably to mean a substance with a species capable of reacting with the substrate surface or material on the substrate surface in a surface reaction (e.g., chemisorption, oxidation, reduction). For example, a first “reactive gas” may simply adsorb onto the surface of a substrate and be available for further chemical reaction with a second reactive gas.

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or "refreshing" to maintain this voltage for more than very short periods of time. Static random-access memories (SRAM) are so named because they do not require periodic refreshing.

As used herein, the term "dynamic random access memory" or "DRAM" refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term "field effect transistor" or "FET" refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET’s three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal–oxide–semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal–oxide–semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a "+" sign after the type of doping.

If the MOSFET is an n-channel or nMOS FET, then the source and drain are n+ regions, and the body is a p region. If the MOSFET is a p-channel or pMOS FET, then the source and drain are p+ regions, and the body is a n region. The source is so named because it is the source of the charge carriers (electrons for n-channel, holes for p-channel) that flow through the channel; similarly, the drain is where the charge carriers leave the channel.

As used herein, the term "fin field-effect transistor (FinFET)" refers to a MOSFET transistor built on a substrate where the gate is placed on two or three sides of the channel, forming a double- or triple-gate structure. FinFET devices have been given the generic name FinFETs because the channel region forms a "fin" on the substrate. FinFET devices have fast switching times and high current density.

As used herein, the term "gate all-around (GAA)", is used to refer to an electronic device, e.g., a transistor, in which the gate material surrounds the channel region on all sides. The channel region of a GAA transistor may include nanowires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term "nanowire" refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices.

As used herein, the term "3D NAND" refers to a type of electronic (solid-state) non-volatile computer storage memory in which the memory cells are stacked in multiple layers. 3D NAND memory generally includes a plurality of memory cells that include floating-gate transistors. Traditionally, 3D NAND memory cells include a plurality of NAND memory structures arranged in three dimensions around a bit line.

Silicon nitride (SiₓN_{y}) films are important for the microelectronics manufacturing, particularly as diffusion barrier layers, passivation layers, etch stop layers, electric insulation layers, antireflection coatings, or as hardmasks for etching, in logic and memory devices. The broadband transparency and low index-contrast with silicon dioxide, make silicon nitride highly valuable in photonics. Silicon nitride films are particularly useful for creating low-loss, low-phase-error waveguides, and are a strong candidate to supplement or replace silicon-on-insulator in silicon photonics. Silicon nitride has advanced ultra-low-loss waveguides, chip-scale nonlinear photonics, and applications in telecommunications, sensing, and metrology due to high refractive index, flexible dimension control, and superior interface properties. Hydrogen bonds, e.g., Si-H and N-H, in silicon nitride (SiₓN_{y}) films cause high propagation loss, particularly in the telecom spectrum (1510-1565 nm for conventional "C" band and 1260-1360 nm for original "O" band).

Silicon nitride films are typically deposited using low-pressure chemical vapor deposition (LPCVD) or plasma enhanced chemical vapor deposition (PECVD). To mitigate hydrogen content, techniques like annealing or using hydrogen-free precursor gases (e.g., switching from NH₃ to N₂) are employed, but the high temperature results in damage to underlying metal layers and other temperature-sensitive components.

One or more embodiments advantageously provide silicon nitride (SiₓN_{y}) films having a low hydrogen content. As used herein, the term "low hydrogen content" means that there is less than or equal to about 8% hydrogen, on an atomic basis, in the silicon nitride film. In some embodiments, there is less than or equal to about 8%, or less than or equal to about 7%, or less than or equal to about 6%, or less than or equal to about 5%, or less than or equal to about 4%, or less than or equal to about 3%, or less than or equal to about 2%, or less than or equal to about 1%, and less than or equal to about 0.5% of hydrogen, on an atomic basis, in the silicon nitride film.

The skilled artisan will recognize that the use of a molecular formula like SiₓN_{y} does not imply a specific stoichiometric relationship between the elements but merely the identity of the major components of the film. For example, SiₓN_{y} refers to a film whose major composition comprises silicon and nitrogen atom. In some embodiments, the major composition of the specified film (i.e., the sum of the atomic percent of silicon (Si) and nitrogen (N)) is greater than or equal to about 90%, 92%, 93%, or 95% of the film, on an atomic basis.

In one or more embodiments, the method involves the use of a microwave plasma chemical vapor deposition (MPCVD) chamber and process gases. No annealing or treatment of the film is necessary. Accordingly, in one or more embodiments, the method is conducted in the absence of annealing and/or treatment. In one or more embodiments, hydrogen-containing precursors may be utilized.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

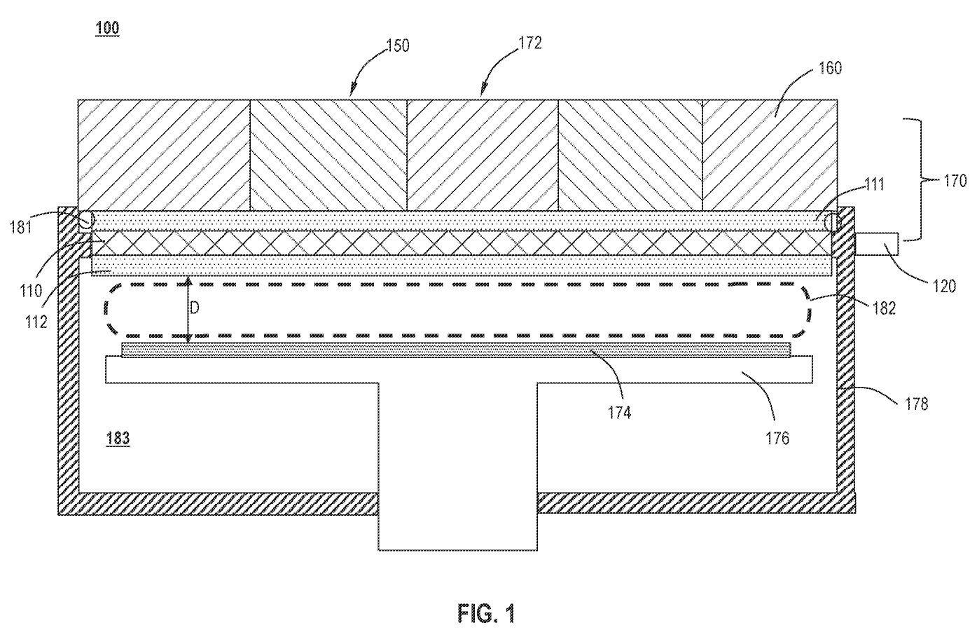

One or more embodiments of the disclosure are described with reference to the Figures. FIG. 1 illustrates a cross-sectional view of a processing tool 100 according to one or more embodiments. In one or more embodiments, the processing tool 100 may be a microwave plasma chemical vapor deposition (MPCVD) chamber which may include one or more of a showerhead, electrodes, resonators, linear antenna, and the like. In one or more embodiments, the processing tool 100 comprises a semiconductor processing chamber 178 that is sealed by a microwave source assembly 170. For example, the microwave source assembly 170 may rest against one or more o-rings 181 to provide a vacuum seal to an interior volume 183 of the semiconductor processing chamber 178. In other embodiments, the microwave source assembly 170 may interface with the semiconductor processing chamber 178. That is, the microwave source assembly 170 may be part of a lid that seals the semiconductor processing chamber 178. In some embodiments, the processing tool 100 may comprise a plurality of processing volumes (which may be fluidically coupled together), with each processing volume having a different microwave source assembly 170.

In some embodiments, a chuck 176 or the like may support a workpiece 174 (e.g., semiconductor wafer, substrate, etc.). In one or more embodiments, the microwave source assembly 170 is spaced a distance D from the workpiece 174. The distance D may be any suitable distance. In some embodiments, the chamber interior volume 183 may be suitable for striking a plasma 182. That is, the semiconductor processing chamber 178 may be a vacuum chamber. In one or more embodiments, the plasma source, or source assembly 170 is positioned at a distance D from the top surface of the workpiece 174. In some embodiments, the distance, D, is greater than or equal to 0.5 mm, or greater than or equal to 10 mm, or greater than or equal to 15 mm, or greater than or equal to 20 mm, or greater than or equal to 25 mm. In one or more embodiments, the distance, D, is in a range of from 0.5 mm to 100 mm.

In one or more embodiments, the microwave source assembly 170 comprises the source array 150 and the housing 172. In one or more embodiments, a permeable barrier 110 is located between a dielectric plate 160 and the workpiece 174. The permeable barrier 110 of some embodiments comprises a plurality of plates 111, 112 (e.g., a top plate 111 and a bottom plate 112).

In some embodiments, the permeable barrier 110 acts as an ion filter to remove ions from the plasma generated at the dielectric plate 160, leaving substantially only radicals. In some embodiments, the permeable barrier 110 filters ions from the microwave plasma 182 while removing residue from the surface of the workpiece 174.

In one or more embodiments, openings in the plurality of plates 111, 112 are offset to prevent ions from moving in a straight path between the plasma 182 generated at the dielectric plate 160 and the workpiece 174.

While the embodiment illustrated in the Figures has two plates 111, 112, the skilled artisan will recognize that there can be more than two adjacent plates. For example, in some embodiments, there are three, four or five plates positioned adjacent to each other. Each plate of some embodiments is spaced a distance from the adjacent plate(s) to allow a gas to pass through the permeable barrier 110.

The permeable barrier 110 can be made of any suitable material. In some embodiments, the permeable barrier 110 comprises one or more of quartz, ceramic, a dielectric material or a metal.

In one or more embodiments, the processing chamber 100 includes a side inlet 120 adjacent the source assembly 170. In some embodiments, the side inlet 120 may be used to introduce one or more of a gaseous flow, a liquid, and/or solid precursor to produce the plasma 182.

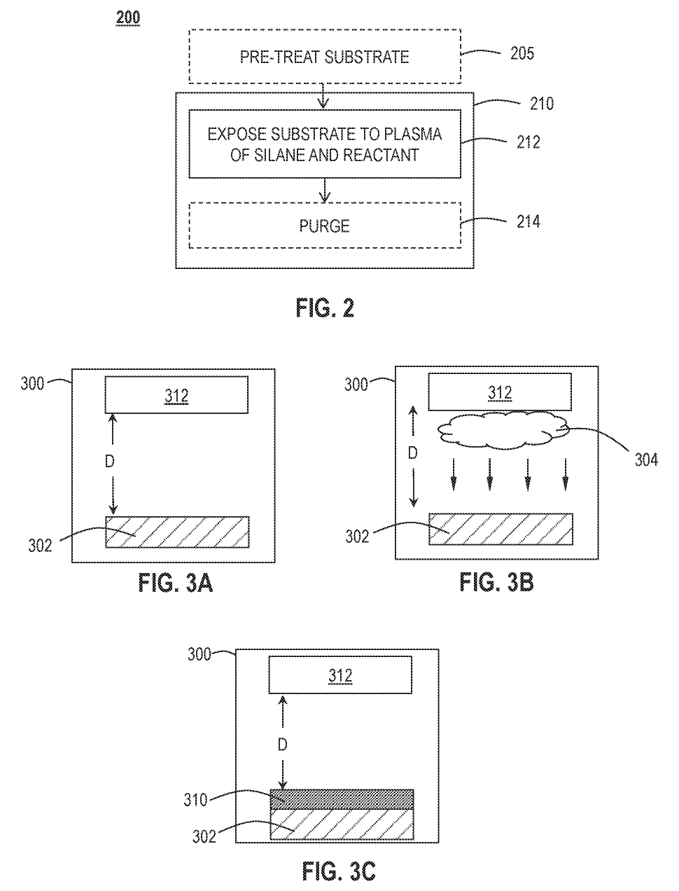

FIG. 2 illustrates a process flow diagram of a method 100 according to one or more embodiments. FIGS. 3A-3C illustrate schematic cross-sectional views of a substrate being processed according to the method of one or more embodiments.

With reference to FIGS. 2 and 3A-3C, one or more embodiments of the disclosure are directed to a method 200 of depositing a film 310. The method illustrated in FIG. 2 is representative of chemical vapor deposition (CVD) process in which the substrate or substrate surface is exposed to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film 310. In one or more embodiments, the chemical vapor deposition process is a microwave plasma chemical vapor deposition (MPCVD) process. In some embodiments, the microwave plasma 304 is a remote microwave plasma. In other embodiments, the microwave plasma 304 is a direct microwave plasma.

In some embodiments, the method 200, a microwave plasma chemical vapor deposition (MPCVD) process, includes a pre-treatment operation 205. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 205. In one or more embodiments, pre-treatment operation 205 is not required.

At deposition 210, a process is performed to deposit a silicon nitride (SiₓN_{y}) film 310 on the substrate 302 (or substrate surface). The deposition process can include one or more operations to form a silicon nitride (SiₓN_{y}) film 310 on the substrate 302. In operation 212, the substrate 302 (or substrate surface) is exposed to a silicon-containing plasma 304 to deposit a film on the substrate (or substrate surface). The silicon-containing plasma 304 can be any suitable silicon-containing compound and reactive gases that can react with the silicon-containing compound to leave a silicon nitride species on the substrate surface.

In one or more embodiments, the sample is processed with a plasma having a silicon-containing compound (SiₓH_{z} where z is greater than or equal to (≥) x). In one or more embodiments, the microwave plasma may include, in addition to the silicon-containing compound, one or more of nitrogen (N₂), ammonia (NH₃), helium (He), argon (Ar), and hydrogen (H₂). In one or more embodiments, the gas stream comprising the silicon-containing compound (SiₓH_{z} where z≥x) is co-flowed with one or more of nitrogen (N₂), ammonia (NH₃), helium (He), argon (Ar), and hydrogen (H₂) during plasma generation. The gases may be co-flowed, flow separately and/or be flowed in different combinations in single or multi-step process.

In one or more embodiments, the silicon-containing compound is selected from one or more of silane (SiH₄), disilane (Si₂H₆), trisilane (Si₃H₈), tetrasilane (Si₄H₁₀), and the like. In one or more embodiments, the silicon-containing compound (SiₓH_{z} where z≥x) is introduced into the microwave plasma processing chamber via the side-inlet 120 of the processing chamber. In some embodiments, the silicon-containing compound (SiₓH_{z} where z≥x) may be introduced as one or more of a gaseous flow, a liquid, and/or as a solid silicon-based precursor to produce the silicon-containing compound. In some embodiments, a carrier gas such as argon (Ar) and/or helium (He) is co-flowed with the silicon-containing compound via the side-inlet 120.

In one or more embodiments, the gas stream and the microwave plasma 304 comprise from 1% to 99% silicon-containing compound (SiₓH_{z} where z≥x), or from 5% to 95% silicon-containing compound (SiₓH_{z} where z≥x) to form the silicon nitride (SiₓN_{y}) film 310 on the substrate 302 surface.

As used herein, a "substrate surface" refers to any substrate surface upon which a layer may be formed. The substrate surface may have one or more features formed therein, one or more layers formed thereon, and combinations thereof. The substrate (or substrate surface) may be pretreated prior to the deposition of the silicon nitride (SiₓN_{y}) film, for example, by polishing, etching, reduction, oxidation, halogenation, hydroxylation, annealing, baking, or the like.

The substrate 302 may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate. For example, in some embodiments, a layer comprising a metal, a nitride, an oxide, or the like, or combinations thereof may be disposed on the substrate and may have the silicon nitride (SiₓN_{y}) layer and/or the silicon oxide (SiOₓ) layer formed upon such layer or layers.

In one or more embodiments, the microwave plasma 304 of the deposition 210 may be generated remotely or within the processing chamber 300. In one or more embodiments, the plasma is microwave plasma 304. Any suitable power can be used depending on, for example, the reactants, or the other process conditions. In some embodiments, the microwave plasma 304 is generated with a plasma power greater than 50 W.

In some embodiments, the substrate 302 is exposed to the gas stream and the microwave plasma 304 for a time period in a range of from 1 second to 14,400 seconds, or as required to achieve the desired film thickness.

At operation 214, the processing chamber 300 is optionally purged to remove unreacted plasma and reactants. In some embodiments, purging the processing chamber comprises applying a vacuum. In some embodiments, purging the processing chamber comprises flowing a purge gas over the substrate. In one or more embodiments, the purge gas is selected from one or more of nitrogen (N₂), helium (He), and argon (Ar).

The method 200 can be performed at any suitable temperature depending on, for example, the silicon-containing precursor, reactant, or thermal budget of the device. In one or more embodiments, the use of high temperature processing may be undesirable for temperature-sensitive substrates, such as logic devices. In some embodiments, the method 200 is performed at a low temperature. In some embodiments, the method 200 is performed at a temperature in a range of from 100 °C to 550 ˚C.

The method 200 can be performed at any suitable pressure. In one or more embodiments, the method 200 is performed at a pressure in a range of from 0.05 Torr to 10 Torr.

In one or more embodiments, the substrate 302 (or substrate surface) is exposed to the silicon-containing plasma 304 and the reactant simultaneously in a microwave plasma CVD (MPCVD) reaction. In an MPCVD reaction, the substrate (or substrate surface) can be exposed to a gaseous mixture of the silicon-containing precursor and reactant to deposit a silicon nitride (SiₓN_{y}) film 310 having a predetermined thickness. In the MPCVD reaction, the silicon nitride (SiₓN_{y}) film 310 can be deposited in one exposure to the mixed plasma reactive gas or can be multiple exposures to the mixed plasma reactive gas with purges between.

The deposition operation 210 can be repeated to form a silicon nitride (SiₓN_{y}) film having a predetermined thickness in the range of from 0.3 nm to 3000 nm, from 0.3 nm to 2000 nm, from 0.3 nm to 1000 nm, from 0.3 nm to 500 nm, from 0.3 nm to 400 nm, from 0.3 nm to 300 nm, from 0.3 nm to 200 nm, from 0.3 nm to 100 nm, from 1 nm to 3000 nm, from 1 nm to 2000 nm, from 1 nm to 1000 nm, from 1 nm to 500 nm, from 1 nm to 400 nm, from 1 nm to 300 nm, from 1 nm to 200 nm or from 1 nm to 100 nm.

One or more embodiments of the disclosure are directed to methods of depositing silicon nitride (SiₓN_{y}) films in high aspect ratio features, e.g., in memory devices or logic devices, including, but not limited to, 3D NAND, DRAM, 3D DRAM, FinFET, GAA, and the like. A high aspect ratio feature is a trench, via, or pillar having a height:width ratio greater than or equal to about 10, 20, or 50, or more. In some embodiments, the silicon nitride (SiₓN_{y}) film is deposited conformally on the high aspect ratio feature. As used in this manner, a conformal film has a thickness near the top of the feature that is in the range of about 80-120% of the thickness at the bottom of the feature.

According to one or more embodiments, the substrate is subjected to processing prior to and/or after forming the layer. This processing can be performed in the same chamber or in one or more separate processing chambers. In some embodiments, the substrate is moved from the microwave processing chamber to a separate, second chamber for further processing. The substrate can be moved directly from the microwave processing chamber to the separate processing chamber, or it can be moved from the microwave processing chamber to one or more transfer chambers and then moved to the separate processing chamber. Accordingly, the processing apparatus may comprise multiple chambers in communication with a transfer station. An apparatus of this sort may be referred to as a "cluster tool" or "clustered system," and the like.

Generally, a cluster tool is a modular system comprising multiple chambers which perform various functions including substrate center-finding and orientation, degassing, annealing, deposition and/or etching. According to one or more embodiments, a cluster tool includes at least a microwave processing chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. The exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or "load lock" conditions and is not exposed to ambient air when being moved from one chamber to the next. The transfer chambers are thus under vacuum and are "pumped down" under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Microwave Plasma Chemical Vapor Deposition of Silicon Nitride Containing Films

General procedure: A silicon substrate was placed in a processing chamber. A silane precursor flowed into the processing chamber from the side-inlet in an atmosphere of nitrogen (N₂) gas and was ignited to form a silane-containing plasma. The silicon substrate was exposed to the silane-containing plasma to leaving a silicon nitride film on the substrate surface. The plasma and byproducts were removed from the chamber. The resulting material on the substrate was a silicon nitride film.

Conclusions: The resulting silicon nitride film had a hydrogen content less than or equal to 8%, on an atomic basis. The wet etch rate was less than or equal to 5.4 Å/min. The refractive index of the resulting silicon nitride film was about 2.0, and the film contains less than 1.5% oxygen, on an atomic basis.

Spatially relative terms, such as "beneath," "below," "lower," "above," "upper" and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as "below,” or "beneath" other elements or features would then be oriented "above" the other elements or features. Thus, the exemplary term "below" may encompass both an orientation of above and below. The device may be otherwise oriented (rotated 90 degrees or at other orientations) and the spatially relative descriptors used herein interpreted accordingly.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to "one embodiment," "certain embodiments," "one or more embodiments" or "an embodiment" means that a particular feature, structure, material, or characteristic described in connection with the embodiment is included in at least one embodiment of the disclosure. Thus, the appearances of the phrases such as "in one or more embodiments," "in certain embodiments," "in one embodiment" or "in an embodiment" in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming film, the method comprising:
flowing a gas stream comprising a silicon-containing compound and a reactant into a processing chamber;
igniting the gas stream to form a microwave plasma; and
exposing a semiconductor substrate to the microwave plasma to form a silicon nitride film on a surface of the semiconductor substrate.

2. The method of claim 1, wherein the silicon-containing compound has a general formula of SiₓH_{z} where z ≥ x.

3. The method of claim 1, wherein the silicon-containing compound comprises one or more of silane (SiH₄), disilane (Si₂H₆), trisilane (Si₃H₈), tetrasilane (Si₄H₁₀), and the like.

4. The method of claim 1, wherein the silicon-containing compound is introduced into the processing chamber via a side-inlet.

5. The method of claim 1, wherein the reactant comprises one or more of nitrogen (N₂), ammonia (NH₃), helium (He), argon (Ar), and hydrogen (H₂).

6. The method of claim 1, wherein the gas stream is ignited at a power of greater than 50 W.

7. The method of claim 1, wherein the semiconductor substrate is maintained at a temperature in a range of from 100 ˚C to 550 ˚C.

8. The method of claim 1, wherein the silicon nitride film has a thickness in a range of from 0.3 nm to 3000 nm.

9. The method of claim 1, wherein the silicon nitride film has a hydrogen content of less than or equal to 8% on an atomic basis.

10. The method of claim 1, wherein the processing chamber comprises a plasma source and a pedestal supporting the semiconductor substrate, and the microwave plasma is generated between the plasma source and the pedestal.

11. The method of claim 10, wherein a distance between the semiconductor substrate and the plasma source is greater than 0.5 mm.

12. The method of claim 9, wherein the silicon nitride film is formed in the absence of an annealing step.

13. A method of forming a silicon nitride film on a semiconductor substrate, the method comprising:
exposing a semiconductor substrate to a microwave plasma to form the silicon nitride film, the microwave plasma comprising a silicon-containing compound.

14. The method of claim 13, wherein the silicon-containing compound has a general formula of SiₓH_{z} where z ≥ x.

15. The method of claim 13, wherein the silicon-containing compound comprises one or more of silane (SiH₄), disilane (Si₂H₆), trisilane (Si₃H₈), tetrasilane (Si₄H₁₀) and the like.

16. The method of claim 13, wherein the silicon-containing compound is introduced into the processing chamber via a side-inlet.

17. The method of claim 13, wherein the microwave plasma further comprises one or more of nitrogen (N₂), ammonia (NH₃), helium (He), argon (Ar), and hydrogen (H₂).

18. The method of claim 13, wherein the microwave plasma is generated at a power of greater than 50 W.

19. The method of claim 13, wherein the semiconductor substrate is maintained at a temperature in a range of from 100 ˚C to 550 ˚C.

20. The method of claim 13, wherein the silicon nitride film has a thickness in a range of from 0.3 nm to 3000 nm.

21. The method of claim 13, wherein the silicon nitride film has a hydrogen content of less than or equal to 8% on an atomic basis.

22. The method of claim 21, wherein the silicon nitride film is formed in the absence of an annealing step.
